(19) United States
(12) Patent Application Publication
(10) Pub. No.: US 2014/0202377 A1
(43) Pub. Date: Jul. 24, 2014

(54) CRUCIBLE FOR PRODUCING COMPOUND CRYSTAL, APPARATUS FOR PRODUCING COMPOUND CRYSTAL, AND METHOD FOR PRODUCING COMPOUND CRYSTAL USING CRUCIBLE

(71) Applicant: NIKON CORPORATION, Tokyo (JP)

(72) Inventor: Hidenori SUGISAKI, Tokyo (JP)

(73) Assignee: NIKON CORPORATION, Tokyo (JP)

(21) Appl. No.: 14/163,095

(22) Filed: Jan. 24, 2014

Related U.S. Application Data
(63) Continuation of application No. PCT/JP2012/068792, filed on Jul. 25, 2012.

(30) Foreign Application Priority Data
Jul. 26, 2011 (JP) 2011-163031

(51) Int. Cl. C30B 11/00

(52) U.S. Cl. CPC C30B 11/002
USPC 117/81; 117/223

(57) ABSTRACT

A crucible for use in producing a compound crystal in which a pre-treated product is made by melting a powdery or granular compound raw material and then cooling and solidifying it in a pre-treatment furnace, and the compound crystal is grown by melting the pre-treated product and then cooling and solidifying it in a crystal growing furnace, the crucible comprising: a first member having a bottom portion and a cylindrical portion; and a hollow cylindrical second member that is capable to be connected to the cylindrical portion and to be separated therefrom, wherein: in a state in which the first member and the second member are connected together, a large capacity crucible for manufacture of the pre-treated product is formed; and in a state in which the first member and the second member are separated from one another, a small capacity crucible for crystal growth is formed.

### INCORPORATION BY REFERENCE

This continuation application claims the benefit of PCT/JP2012/068792 filed Jul. 25, 2012. This application also claims priority from Japanese Application No. 2011-163031 filed Jul. 26, 2011. The disclosures of the following applications are herein incorporated by reference:

Japanese Patent Application 2011-163031 (filed on Jul. 26, 2011)

International Application No. PCT/JP2012/068792 (filed Jul. 25, 2012).

### BACKGROUND OF THE INVENTION

1. Field of the Invention

The present invention relates to a crucible for producing a compound crystal, to an apparatus for producing a compound crystal, and to a method for producing a compound crystal, and, in particular, relates to a crucible, a producing apparatus, and a producing method that are appropriate for producing a fluoride crystal for an optical material used in the ultraviolet region.

2. Description of Related Art

In recent years, lithographic technology for drawing integrated circuit patterns upon wafers has developed rapidly. The demand for highly integrated circuits is rising year on year, and, in order to implement this, there is a requirement to increase the resolution of the projection optical systems of projection exposure apparatus. The resolution of a projection optical system depends upon the wavelength of the light that is used and upon the NA (numerical aperture) of the projection optical system. In other words, in order to enhance the resolution, it is necessary either to make the wavelength of the light that is used shorter, or to make the NA of the projection optical system greater (i.e. to increase the diameter of the lens); but it is more advantageous to shorten the wavelength, since when the NA is increased the focal depth becomes shallower, and this is undesirable.

Due to this, shortening of the wavelength of the exposure light for exposure devices has progressed, and currently there is a transition from the use of the g-line (wavelength of 436 nm) and of the i-line (wavelength of 365 nm) to the wavelength region of excimer lasers in which the wavelength is yet shorter. In the optical systems for these exposure devices, it is possible to employ optical glass down to the i-line wavelength region, but it is difficult to employ optical glass for light in the wavelength region of a KrF excimer laser (wavelength 248 nm) or of an ArF excimer laser (wavelength 193 nm), since the transmittance of optical glass in these wavelength regions is low. Due to this, in the optical system of an exposure device that uses a light source in the wavelength region of 250 nm or below, it is usual to employ an optical element that has been made by processing silica glass or that has been made from a fluoride crystal, for example from a single crystal of calcium fluoride (CaF₂).

Calcium fluoride (or fluorite) has a comparatively high transmittance in the 193 nm wavelength region. However, when calcium fluoride is irradiated with ultraviolet light of this type of wavelength having high photon energy over a long time period, it becomes damaged due to light absorption and heating by minute impurities included in the crystal and by lattice defects. Due to this, high purity calcium fluoride that has been chemically synthesized is used in the manufacture of single crystals of calcium fluoride for use as optical elements for use with ArF excimer lasers.

Chemically synthesized high purity calcium fluoride is generally supplied as a raw material in powder form having particle diameter around 0.1 μm, or as a raw material in the form of granules around 5 mm in diameter. Since the bulk density (apparent density) of this type of powdery form or granular form calcium fluoride is low, accordingly its volume decreases remarkably when it is melted down. Due to this, when a comparatively large calcium fluoride single crystal is to be manufactured, it is usual to manufacture a pre-treated product consisting of a polycrystalline bulk by first performing a pre-processing stage of melting a raw material consisting of calcium fluoride in powder form or granular form and then solidifying it, and then performing a subsequent crystal growing stage of again melting this polycrystalline bulk so as to manufacture a single crystal (for example, refer to Patent Documents #1 and #2).

The Bridgman method (generally termed the “vertical Bridgman method” since a vertical type furnace is used, and also called the “Stockbarger method” or the “crucible pulling-down method”) is widely employed as an industrial method for growing a compound single crystal. To cite an example of a process of producing a calcium fluoride crystal that includes a pre-processing stage of melting a raw material in powder form to make a pre-treated product, and a crystal growing stage of growing a single crystal by the Bridgman method, a prior art producing method for a compound crystal and a producing apparatus that utilizes this producing method will now be explained with reference to FIGS. 3A through 3D. In this first structural example of a method for producing a fluoride crystal, a pre-processing crucible 110, a pre-treatment furnace 120, a crystal growth crucible 115, a crystal growing furnace 130, and a control device not shown in the figures are used.

The pre-processing stage of melting the calcium fluoride powder raw material and making the pre-treated product is performed using the pre-processing crucible 110 shown in FIG. 3A and the pre-treatment furnace 120 shown in FIG. 3B. The pre-processing crucible 110 is made from a cone shaped bottom portion 110a and a cylinder-shaped cylindrical portion 110b that is integrated with and extends upwards from the bottom portion 110a, and that is open at its top. In order to be able to accommodate a large quantity of powder raw material charged thereinto, the pre-processing crucible 110 is made as a large capacity crucible, with its cylindrical portion 110b having a comparatively large dimension in the vertical direction.

The pre-treatment furnace 120 comprises: a base plate 121 that constitutes a furnace support; a bell jar 125 that is provided so as to be closed or opened by being is lowered onto the base plate 121 or being raised away therefrom, and that, in the closed state, constitutes a vacuum vessel along with the base plate; a crucible support member 122 that supports the pre-processing crucible 110; a heater 126 that is provided in the interior of the bell jar 125 so as to surround the outer surface of the pre-processing crucible 110; a heat insulating member 127 that covers the interior of the bell jar 125; and a vacuum apparatus (not shown in the figures) or the like that evacuates the interior of the pre-treatment furnace 120 to vacuum.

In the pre-processing stage, first, as shown in FIG. 3A, a powdery compound raw material Pp consisting of calcium fluoride raw material powder and a scavenger mixed together is charged into the pre-processing crucible 110. Next, as shown in FIG. 3B, the pre-processing crucible 110 with the raw material powder Pp charged into it is supported upon the crucible support member 122, and the bell jar 125 is lowered down over the crucible so that it closely contacts against the base plate 121 and forms a seal, thus becoming closed. Then the interior of the vacuum vessel that is thus defined by the base plate 121 and the bell jar 125 is evacuated with the vacuum apparatus, and a vacuum level of around 10⁻³˜10⁻⁴ Pa is established. In this state, heat is supplied to the interior of the vacuum vessel by the heater 126, so that the temperature within the vacuum vessel is raised to the temperature range of 1370° C.˜1450° C., that is higher than the melting point of calcium fluoride, and, after the powder raw material Pp has been melted, the temperature within the vacuum vessel is then allowed to drop back down to room temperature, so that the molten substance is solidified. A pre-treated product Pb that consists of a polycrystalline bulk of calcium fluoride is manufactured in this manner.

Next, the pre-treated product Pb manufactured in the pre-processing stage described above is extracted from the pre-processing crucible 110, and is transferred and placed into a crystal growth crucible 115, as shown in FIG. 3C. This crystal growth crucible 115 also is made from a cone shaped bottom portion 115a and a cylinder-shaped cylindrical portion 115b that is integrated with and extends upwards from the bottom portion 115a, and that is open at its top. The diameter of its cylindrical portion 115b is somewhat larger than that of the cylindrical portion 110b of the pre-processing crucible. The crystal growing stage is a process in which the polycrystalline calcium fluoride that was melted and solidified into a bulk state in the pre-processing stage is re-melted and is formed into a single crystal. In this process, the amount of volume change when thus forming the material from a polycrystalline bulk into a single crystal is small. Due to this, the vertical dimension of the cylindrical portion 115b of the crystal growth crucible 115 is comparatively small, and it is made as a small capacity crucible of a size capable of containing the pre-treated product Pb.

The crystal growing stage is performed using the crystal growth crucible 115 described above and a crystal growing furnace 130 shown in FIG. 3D. This crystal growing furnace 130 comprises: a base plate 131 that constitutes a furnace support; a bell jar 135 that is provided so as to be closed or opened by being lowered onto the base plate 131 or being raised away therefrom, and that, in the closed state, constitutes a vacuum vessel along with the base plate; a crucible support member 132 that supports the crystal growth crucible 115; an up/down drive mechanism 133 that shifts the crystal growth crucible 115 up and down by raising and lowering the crucible support member 132; an upper portion heater 136a and a lower portion heater 136b that are provided in the interior of the bell jar 135 so as to surround the outer surface of the crystal growth crucible 115; a heat insulating member 137 that covers the interior of the bell jar 135; a partitioning heat insulating member 138 that is provided between the upper portion heater 136a and the lower portion heater 136b and that divides the space within the vacuum vessel into a high temperature side furnace chamber 130a and a low temperature side furnace chamber 130b; and a vacuum apparatus (not shown in the figures) or the like that evacuates the interior of the vacuum vessel to vacuum.

As a result of the above task of transferring that has been explained with reference to FIG. 3C, the crystal growth crucible 115 containing the crystal pre-treated product Pb that has been transferred from the pre-processing crucible is brought to be supported upon the crucible support member 132. And, by lowering the bell jar 135 and closely contacting it against the base plate 131, the interior of the bell jar 135 is closed, and then the space within the vacuum vessel defined by the base plate 131 and the bell jar 135 is evacuated by the vacuum apparatus, and a vacuum of 10⁻³˜10⁻⁴ Pa is established and maintained. At this time, the crystal growth crucible 115 is set by the up/down drive mechanism 133 to a higher position in the vertical direction of the crystal growth crucible 115, so that the crystal growth crucible 115 is positioned within the high temperature side furnace chamber 130a. After the interior of the vacuum vessel has reached the above described vacuum state, heat is applied within the vacuum vessel by the upper portion heater 136a, and the temperature within the vacuum vessel is raised to the temperature range of 1370° C.˜1450° C., and this is higher than the melting point of calcium fluoride, so that the pre-treated product Pb is melted. Next, the crystal growth crucible 115 is pulled downwards by the up/down drive mechanism 133 towards the low temperature side is furnace chamber 130b at a speed of around 0.1˜5 mm/h, so that a crystal Pc is gradually grown from the lower portion of the crystal growth crucible 115. At this time, the lower portion heater 136b is set to a lower temperature than the upper portion heater 136a. The crystal growth ends when the crystallization has proceeded all the way to the uppermost portion of the calcium fluoride that was in the molten state.

In the above explanation, as a first structural example of a prior art method for producing a compound crystal, and citing manufacture of a calcium fluoride crystal by way of example, a technique for growing a crystal was disclosed in which the pre-treated product Pb is manufactured by charging the powder raw material Pp into the pre-processing crucible 110, melting it with the pre-treatment furnace 120, and then allowing it to solidify; and then the pre-treated product Pb manufactured in this manner is transferred into the crystal growth crucible 115, and, after it has been melted for a second time in the crystal growing furnace 130, it is allowed to solidify. Next, as a second structural example of a prior art method for producing a compound crystal, and again citing manufacture of a calcium fluoride crystal by way of example, a technique in which there is no requirement to perform the above task of transferring the pre-treated product Pb will be explained with reference to FIGS. 4A through 4C.

It should be understood that, in this structural example, the crystal growth crucible 215 is a comparatively large sized one of the same general size as the pre-processing crucible 110 described above, and the crystal growing furnace 230 is a large sized one that matches the size of the crystal growth crucible 215. However, the fundamental structures of the pre-treatment furnace and the crystal growing furnace are the same as in the case of the first structural example described above. Accordingly, to portions that are the same, the same reference symbols will be appended and explanation thereof will be omitted, while only the portions that differ will be explained in a concise manner. The producing apparatus for a calcium fluoride crystal of this structural example comprises a pre-treatment furnace 120, a crystal growth crucible 215, a crystal growing furnace 230, and a control device or the like not shown in the figures.

According to the producing method according to this structural example, no dedicated pre-processing crucible is used while the pre-processing is being performed, but instead the pre-treated product is manufactured by charging the powder raw material into the crystal growth crucible 215 and melting it, and then subsequently solidifying it. In a similar manner to the crystal growth crucible 115 described above, the crystal growth crucible 215 is made from a cone shaped bottom portion 215a and a cylinder-shaped cylindrical portion 215b that is integrated with and extends upwards from the bottom portion 215a, and that is open at its top. As described above, the bulk density of the raw material powder is low, and, with a volume of raw material powder of the same order as that of the crystal growth crucible 115 described above, it is not possible to grow a single crystal of sufficient size. Due to this, the vertical dimension of the cylindrical portion 215b of the crystal growth crucible 215 is made to be greater than that of the cylindrical portion 115b of the crystal growth crucible 115, so that a large capacity crucible results having a volume equal to that of the pre-processing crucible 110.

The pre-processing stage shown in FIG. 4B is performed in a similar manner to the pre-processing stage explained above with reference to FIG. 3B. That is, the crystal growth crucible 215 with the powder raw material Pp charged into it is supported upon the crucible support member 122 and is enclosed by the bell jar 125 being sealed against the base plate 121, and the interior of the vacuum vessel defined by the base plate 121 and the bell jar 125 is then evacuated so that the pressure therein is brought down to a predetermined vacuum level. When this predetermined vacuum level has been reached, heat is applied to the interior of the vacuum vessel by the heater 126, so that the temperature within the vacuum vessel is raised to a temperature higher than the melting point of calcium fluoride. After the powder raw material Pp has thus been melted, the temperature within the vacuum vessel is lowered to room temperature so that the material Pp solidifies, and thereby a pre-treated product Pb consisting of a polycrystalline bulk of calcium fluoride is manufactured.

Next, the crystal growth crucible 215 that contains the pre-treated product Pb in its interior is taken out of the pre-treatment furnace 120, and is supported upon the crucible support member 132 within the crystal growing furnace 230, as shown in FIG. 4C. The crystal growing furnace 230 is a large size furnace whose size matches that of the crystal growth crucible 215. It should be understood that the volume of the pre-treated product Pb obtained in the pre-processing stage (i.e. the height of the upper surface of the pre-treated product Pb) is of approximately the same order as the volume of the pre-treated product in the first structural example described above. Due to this, in the crystal growing furnace 230, the volume of the high temperature side furnace chamber 230a that is above the partitioning heat insulating member 138 is greater than the volume of the low temperature side furnace chamber 130b that is below the partitioning heat insulating member 138, and the bell jar 235 is made to be larger than the bell jar 125 of the crystal growing furnace 230 in the first structural example, while the upper portion heater 236a and the heat insulating member 237 are also made to be large in size.

The crystal growing stage shown in FIG. 4C is performed in a similar manner to the crystal growing stage explained above with reference to FIG. 3D. That is, the crystal growth crucible 215 that is holding the solidified pre-treated product Pb in its interior is supported upon the crucible support member 132, and the bell jar 235 is sealed onto the base plate 131, thus enclosing the crucible 215. Then the interior of the vacuum vessel defined by the base plate 131 and the bell jar 235 is evacuated to a predetermined vacuum level. At this time, the position of the crystal growth crucible 215 in the vertical direction is set by the up/down drive mechanism 133 so that the entire crystal growth crucible 215 is positioned within the high temperature side furnace chamber 230a. When the interior of the vacuum vessel has reached the predetermined vacuum level, then heat is applied by the upper portion heater 236a, and the temperature within the vacuum vessel is raised to the melting point of calcium fluoride or higher, so that the pre-treated product Pb is melted. Next, the crystal growth crucible 215 is pulled downward by the up/down drive mechanism 133 towards the low temperature side furnace chamber 130b, and a crystal Pc is gradually grown from the lower portion of the crystal growth crucible 215. At this time, the lower portion heater 136b is set to a lower temperature than the upper portion heater 236a. The crystal growth is completed when the crystallization has progressed as far as the uppermost portion of the calcium fluoride, that was in the molten state.

### SUMMARY

The following problems present themselves with the prior art methods explained above (see Japanese Patent 4,569,872 and Japanese Laid-open Patent Publication 2002-308694) for producing a compound crystal and producing apparatus. First, in the producing method of the first structural example explained with reference to FIGS. 3A through 3D, between the pre-processing stage and the crystal growing stage, it is necessary to perform the task of transferring the pre-treated product from the pre-processing crucible into the crystal growth crucible (refer to FIG. 3C). The fact that this type of transferring task increases the producing cost due to the requirement for a greater number of working stages, also there is a danger that, during this transferring task, the optical characteristics may become deteriorated due to metallic impurities becoming mixed into the material, or due to the absorption of oxygen.

On the other hand, in the producing method of the second structural example explained with reference to FIGS. 4A through 4C, such a transferring task of moving the pre-treated product over from the pre-processing crucible into the crystal growth crucible is not included. However, it is necessary to employ a crystal growth crucible of high capacity, since the same crystal growth crucible 215 is used both in the pre-processing stage of melting the powder raw material whose bulk density is low and thus making the pre-treated product, and in the crystal growing stage. Due to this, it is necessary to employ a large size crystal growing furnace (refer to FIGS. 3D and 4C together). This increase in the size of the crystal growing furnace causes the problem of increase in the cost of the facility, and also raises the producing cost.

According to the first aspect of the present invention, a crucible for use in producing a compound crystal, the crucible comprises: a first member having a bottom portion and a cylindrical portion integrated with the bottom portion; and a second member that is hollow cylindrical and can be put into either a state of being connected to the cylindrical portion or into a state of being separated therefrom, wherein: in a state in which the first member and the second member are connected together, a large capacity crucible for manufacture of a pre-treated product is formed; and in a state in which the first member and the second member are separated from one another, a small capacity crucible for crystal growth is formed.

According to the second aspect of the present invention, in the crucible for use in producing a compound crystal of the first aspect, it is preferred that the compound is fluoride.

According to the third aspect of the present invention, an apparatus for producing a compound crystal, comprises: a vacuum vessel; a crucible; and a heater provided in the interior of the vacuum vessel, wherein: the crucible comprises a first member comprising a bottom portion and a cylindrical portion integrated with the bottom portion, and a second member that is hollow cylindrical and can be put either into a state of being connected to the cylindrical portion of the first member or into a state of being separated therefrom.

According to the fourth aspect of the present invention, in the apparatus for producing a compound crystal of the third aspect, it is preferred that the compound crystal is a fluoride crystal.

According to the fifth aspect of the present invention, an apparatus for producing a compound crystal, comprises: a vacuum vessel; a crucible support member that supports a crucible in the interior of the vacuum vessel: an up/down drive mechanism that shifts the crucible in the vertical direction by raising and lowering the crucible support member; and an upper portion heater and a lower portion heater provided in the interior of the vacuum vessel, wherein: the crucible comprises a first member comprising a bottom portion and a cylindrical portion integrated with the bottom portion, and a second member that is hollow cylindrical and can be put either into a state of being connected to the cylindrical portion of the first member or into a state of being separated therefrom; and the crucible support member is configured to support the first member of the crucible in a state in which the second member of the crucible is separated from the first member.

According to the sixth aspect of the present invention, in the apparatus for producing a compound crystal of the fifth aspect, it is preferred that the compound is fluoride.

According to the seventh aspect of the present invention, a method for producing a compound crystal using a crucible, the method comprises the steps of: preparing step for preparing the crucible that comprises a first member having a bottom portion and a cylindrical portion integrated with the bottom portion, and a second member that is hollow cylindrical and can be put either into a state of being connected to the cylindrical portion or into a state of being separated therefrom; a pre-processing step for making a pre-treated product for the compound crystal in the interior of the first member by, charging a raw material into the crucible in a state in which the second member is connected to the first member, melting the raw material, and then solidifying melted raw material; a crucible separation step for separating the second member from the first member; and a crystal growing step for melting the pre-treated compound product that has been made in the interior of the first member, and then solidifying melted pre-treated compound product and growing a crystal of the compound.

According to the eighth aspect of the present invention, in the method for producing a compound crystal using a crucible in the seventh aspect, it is preferred that the compound is fluoride.

Since it is not necessary to perform any task of transferring the pre-treated product between the pre-processing stage and the crystal growing stage of growing the compound single crystal, accordingly to that extent it is possible to reduce the producing cost; and, simultaneously, it is possible to prevent mixing in of metallic impurities or the like during such a transferring task, so that it is possible to reduce the producing cost and to obtain a compound single crystal of high quality. Moreover, since in the crystal growing stage it is possible to employ the crucible in its small capacity configuration, and since it is therefore possible to use a compact crystal growing furnace, accordingly it is possible to keep down the expense of the facility and to reduce the producing cost from this aspect as well.

### BRIEF DESCRIPTION OF THE DRAWINGS

FIGS. 1A through 1D are schematic explanatory figures for explanation of a crucible for producing a compound crystal and an apparatus and method for producing a compound crystal, shown as an example of an embodiment of the present invention;

FIGS. 2A through 2C are schematic figures showing a structural example of a connection portion of the crucible described above;

FIGS. 3A through 3D are schematic explanatory figures for explanation of an apparatus and a method for producing a compound crystal, these being a first structural example of the prior art; and

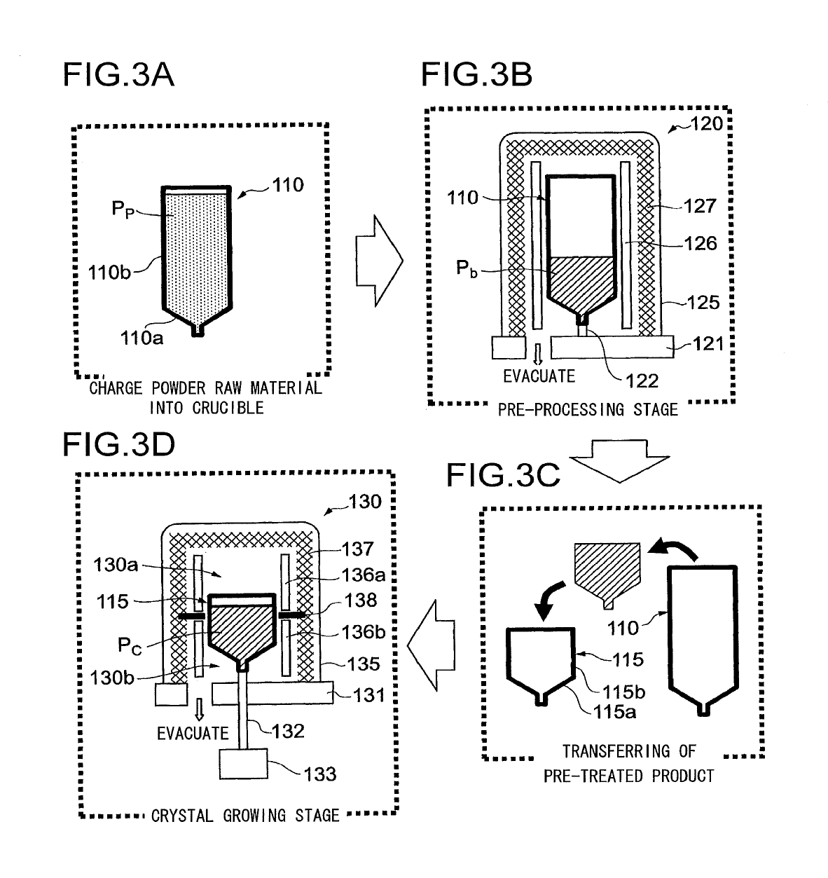

FIGS. 4A through 4C are schematic explanatory figures for explanation of an apparatus and a method for producing a compound crystal, these being a second structural example of the prior art.

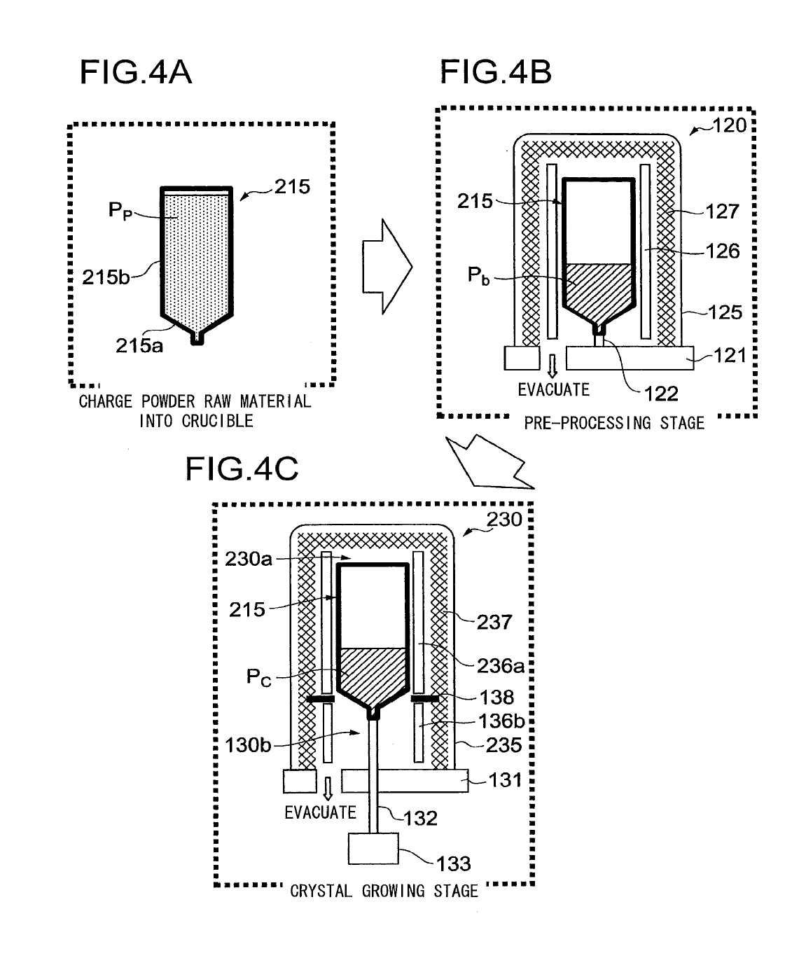

### DESCRIPTION OF PREFERRED EMBODIMENTS

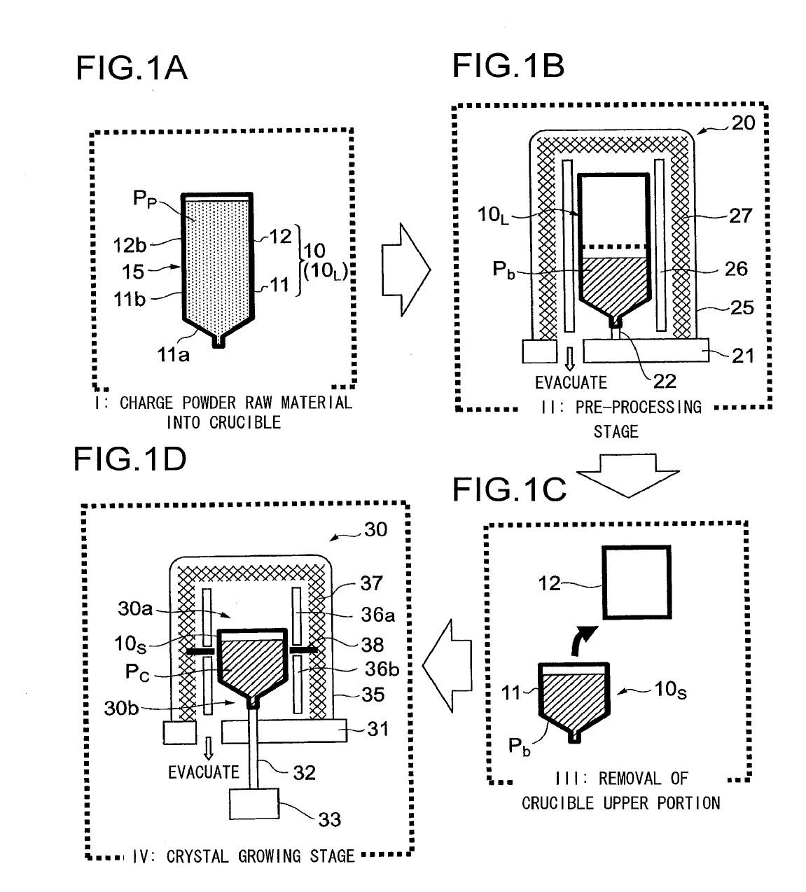

An embodiment of the present invention will now be explained with reference to FIGS. 1A through 1D. FIGS. 1A through 1D are schematic explanatory figures for explanation of a producing apparatus and a producing method, for showing an example of producing a calcium fluoride single crystal according to an embodiment of the present invention.

In the manufacture of a calcium fluoride single crystal according to this embodiment, a crucible 10, a pre-treatment furnace 20, a crystal growing furnace 30, and a control device or the like not shown in the drawings are used. As shown in FIG. 1A through ID, the crucible 10 is built with a first member 11 consisting of a bottom portion 11a and a cylindrical portion 11b that is integrated with and extends upwards from the bottom portion, and a hollow cylindrical second member 12 that can be put either into the state of being fixed to the cylindrical portion 11b of the first member, or into the state of being separated therefrom. The first member 11 and the second member 12 that constitute the crucible 10 are formed using a material, for example isotropic graphite, that is capable of withstanding the high temperature states in the interiors of the pre-treatment furnace 20 and the crystal growing furnace 30, and that simultaneously is not eluted by any metallic impurities or the like within the molten calcium fluoride.

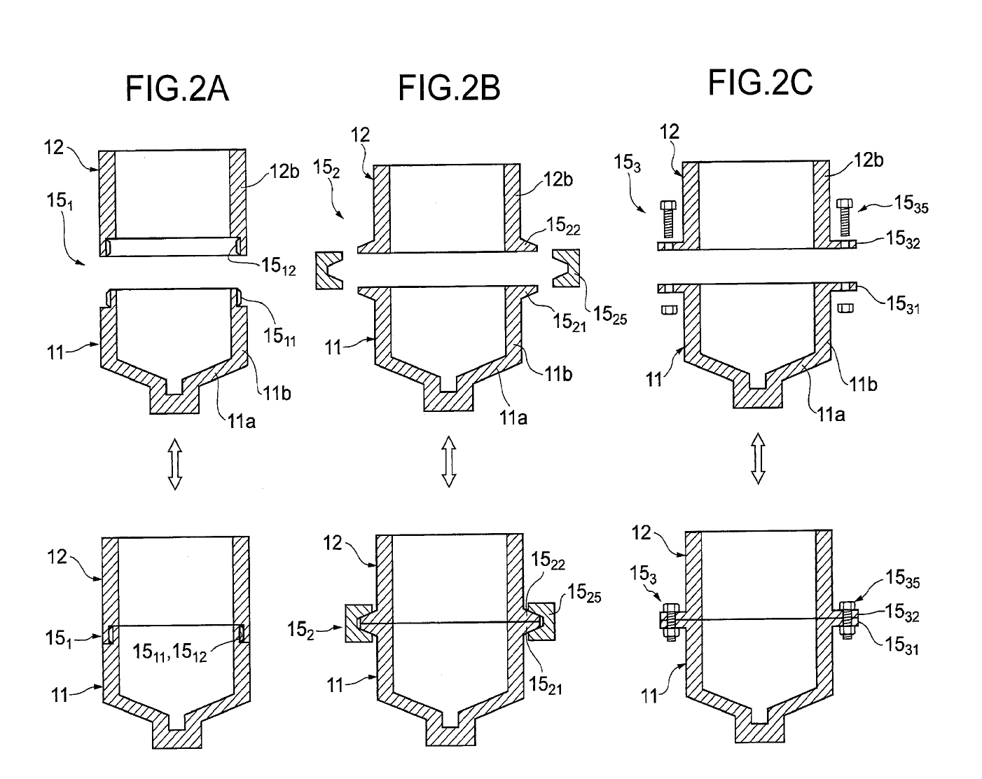

A connection construction 15 is provided at the upper end portion of the cylindrical portion 11b of the first member 11 and at the lower end portion of the cylindrical portion 12b of the second member 12, and functions so that they can be either mutually connected together or separated from one another, with the two of them constituting a single integrated cylindrical portion when they are thus connected together. Structural examples of this connection construction 15 are shown in FIGS. 2A through 2C as 15₁, 15₂, and 15₃.

The connection construction 15₁ according to the first structural example shown in FIG. 2A is an example in which the detachable connection construction is built with a pair 15₁₁ and 15₁₂ consisting of a male screw and a female screw. As shown in the upper part of FIG. 2A, the male screw 15₁₁ is formed around the outer circumferential surface of the upper end portion of the cylindrical portion 11b of the first member 11, and the female screw 15₁₂ is formed around the inner circumferential surface of the lower end portion of the cylindrical portion 12b, so as to be capable of screw engagement with the male screw 15₁₁. With this type of structure, as shown in the lower part of FIG. 2A, when the female screw 15₁₂ is screwed over and engaged to the male screw 15₁₁ so that the first member 11 and the second member 12 become connected together, then these two members 11 and 12 are integrated into a single body, so as to define a large capacity crucible for manufacture of the pre-treated product. Moreover, when the screw engagement of the male screw 15₁₁ and the female screw 15₁₂ is undone and the first member 11 and the second member 12 are separated, then the first member 11 constitutes a small capacity crucible for crystal growth. It should be understood that while, in this example, the male screw 15₁₁ is shown as being formed upon the side of the first member 11 and the female screw 15₁₂ is shown as being formed upon the side of the second member 12, it would also be possible to reverse this combination of the male screw and the female screw (so that the female screw 15₁₂ is on the side of the first member 11).

The connection construction 15₂ according to the second structural example shown in FIG. 2B is an example in which the detachable connection construction is built with a pair of taper flanges 15₂₁ and 15₂₂ and a clamp 15₂₅. As shown in the upper part of FIG. 2B, the pair of taper shaped taper flanges 15₂₁ and 15₂₂ are formed at the upper end portion of the cylindrical portion 11b of the first member 11 and at the lower end portion of the cylindrical portion 12b of the second member 12 respectively, around their external circumferences. And the internal circumferential portion of the clamp 15₂₅ is formed with taper surfaces that contact the surfaces of the taper flanges 15₂₁ and 15₂₂. With this type of structure, when, as shown in the lower part of FIG. 2B, with the taper flange 15₂₁ of the first member and the taper flange 15₂₂ of the second member being contacted together, the clamp 15₂₅ is fitted around their external circumferences and is clamped up (so that the diameter of the clamp becomes smaller), then the first member 11 and the second member 12 become connected together and these two members 11 and 12 are integrated into a single body, so as to define a large capacity crucible for manufacture of the pre-treated product. Moreover, when the clamp 15₂₅ is removed and the connection of the taper flanges 15₂₁ and 15₂₂ is broken so that the first member 11 and the second member 12 are separated, then the first member 11 constitutes a small capacity crucible for crystal growth.

The connection construction 15₃ according to the third structural example shown in FIG. 2C is an example in which the detachable connection construction is built with a pair of flanges 15₃₁ and 15₃₂ and with engagement fixings 15₃₅ each of which consists of a bolt and a nut. As shown in the upper part of FIG. 2C, the circular plate shaped flanges 15₃₁ and 15₃₂ are formed at the upper end portion of the cylindrical portion 11b of the first member 11 and at the lower end portion of the cylindrical portion 12b of the second member 12 respectively. Each of the flanges 15₃₁ and 15₃₂ is formed with holes at a predetermined pitch for insertion of the bolts. Due to this, as shown in the lower part of FIG. 2C, by the flange 15₃₁ of the first member and the flange 15₃₂ of the second member being contacted together with the holes in them being mutually aligned, and by the bolts being passed through these holes and the nuts being fitted onto them, the first member 11 and the second member 12 are connected together and these two members 11 and 12 are integrated into a single body, so as to define a large capacity crucible for manufacture of the pre-treated product. Moreover, when the engagement fixings 15₃₅ are removed and the connection of the flanges 15₃₁ and 15₃₂ is broken so that the first member 11 and the second member 12 are separated, then the first member 11 constitutes a small capacity crucible for crystal growth.

In this manner, the integrated crucible 10 is built so that, when the first member 11 and the second member 12 are connected together using the connection mechanism 15 (15₁, 15₂, or 15₃) so that they are both integrated into a single crucible body, then a large diameter crucible is defined for manufacture of the pre-treated product, whereas, when the connection of the first member 11 and the second member 12 is broken and they are separated, then the first member 11 by itself constitutes a small capacity crucible for crystal growth. The diameter and the height of the first member 11 are set on the basis of the size of the calcium fluoride single crystal that is to be manufactured, while the height of the second member 12 is set so that the volume of the pre-treated product when the powder raw material has solidified after being melted does not become greater than the volume of the first member 11. Subsequently in this specification, when the crucible 10 it is in its large capacity configuration in which the first member 11 and the second member 12 are connected together is to be distinguished from the crucible 10 in its small capacity configuration in which the second member 12 is separated from the first member 11 and is considered by itself, the crucible 10 in its large capacity configuration will be termed the crucible 10_{L}, while the crucible 10 in its small capacity configuration will be termed the crucible 10_{S}.

As shown in FIG. 1B, the pre-treatment furnace 20 comprises a base plate 21 that constitutes a support for the pre-treatment furnace 20, a bell jar 25 that is provided so as to be closed or opened by being lowered onto the base plate 21 or being raised away therefrom, and that, in the closed state, constitutes a vacuum vessel along with the base plate; a crucible support member 22 that supports the crucible 10_{L}; and a vacuum apparatus (not shown in the figures) or the like that evacuates the interior of the pre-treatment furnace 20 to a predetermined vacuum level and maintains that vacuum level. A heater 26 is provided in the interior of the bell jar 25 in a position surrounding the periphery of the crucible 10_{L}, and a heat insulating member 27 is provided over the outside of the heater, so as to cover the inner surface of the bell jar.

The outgassing of the base plate 21 and the bell jar 25 in the high temperature high vacuum state is required to be low, and moreover they are required to have high corrosion resistance with respect to any reactive gas that can possibly be generated within the pre-treatment furnace 20. Due to the above, the base plate 21 and the bell jar 25 are made from stainless steel, that has these characteristics. With regard to the size of the bell jar 25 (i.e. the volume of the pre-treatment furnace 20), its diameter and height are set so that it has an appropriate size to be capable of containing the crucible 10_{L} in the large capacity configuration in which the first member 11 and the second member 12 are connected together, and so that it is thus capable of efficiently melting the powder raw material Pp that has been charged into the crucible 10_{L} in the large capacity configuration and thereby making the pre-treated product.

The crucible support member 22 is heated up to or above the melting point of calcium fluoride, along with the crucible 10_{L}. Due to this, just as for the crucible, the crucible support member 22 is made from a material, for example isotropic graphite, that is capable of withstanding the high temperature state in the interior of the pre-treatment furnace 20, and that simultaneously does not mix with any metallic impurities or the like within the molten calcium fluoride. A heater 26 is used that is capable of raising the temperature to the melting point of calcium fluoride or higher, and its temperature is controlled by a control device not shown in the drawings. The control system for the heater may include a temperature sensor, a temperature adjustment device, an electrical power controller, and so on.

As shown in FIG. 1D, the crystal growing furnace 30 comprises: a base plate 31 that constitutes a support for the crystal growing furnace 30; a bell jar 35 that is provided so as to be closed or opened by being lowered onto the base plate 31 or being raised away therefrom, and that, in the closed state, constitutes a vacuum vessel along with the base plate; a crucible support member 32 that supports the crucible 10_{S}; an up/down drive mechanism 33 that shifts the crucible 10_{S} up and down by raising and lowering the crucible support member 32; and a vacuum apparatus (not shown in the drawings) or the like that evacuates the interior of the crystal growing furnace 30 and maintains it at a predetermined vacuum level. A partitioning heat insulating member 38 is provided in the bell jar 35 and separates the interior of the crystal growing furnace 30 into a high temperature side furnace chamber 30a and a low temperature side furnace chamber 30b, and an upper portion heater 36a provided in the upper high temperature side furnace chamber 30a and a lower portion heater 36b provided in the lower low temperature side furnace chamber 30b are both positioned to surround the periphery of the crucible 10_{S}. Moreover, a heat insulating member 37 is provided to cover the inner surface of the bell jar 32, around the exteriors of the upper portion heater 36a and the lower portion heater 36b.

Similarly to the case with the pre-treatment furnace 20, the interior of the crystal growing furnace 30 is exposed to a high temperature high vacuum state. Due to this, the base plate 31 and the bell jar 35 are made from a material that has low outgassing in the high temperature high vacuum state, and moreover that has stable corrosion resistance with respect to any reactive gas that can be generated within the pre-treatment furnace 30, such as for example stainless steel, that has these characteristics. With regard to the size of the bell jar 35 (i.e. the volume of the crystal growing furnace 30), its diameter and height are set so that it has an appropriate size to be capable of containing the crucible 10_{S} in the small capacity configuration in which the first member 11 and the second member 12 are separated from one another, and so that the pre-treated product Pb in the crucible 10_{S} in its small capacity configuration can be efficiently melted, so as to grow a single crystal by the vertical Bridgman method.

The upper portion of the crucible support member 32 is heated up to or above the melting point of calcium fluoride, along with the crucible 10_{S}. Due to this, at least the upper portion of the crucible support member 32 is made from a material, for example isotropic graphite like the crucible, that is capable of withstanding the high temperature state in the interior of the crystal growing furnace 30, and that simultaneously does not mix with any metallic impurities or the like within the molten calcium fluoride. A heater 36a is used that is capable of raising the temperature to the melting point of calcium fluoride or higher, and its temperature is controlled by a control device not shown in the drawings. The control system for the heater may include a temperature sensor, a temperature adjustment device, an electrical power controller, and so on.

Next, a method for producing a calcium fluoride single crystal will be explained. This producing method comprises a powder raw material charging stage I shown in FIG. 1A, a pre-processing stage II shown in FIG. 1B, a second member separation stage III shown in FIG. 1C, and a crystal growing stage IV shown in 1D of the same figure.

In the powder raw material charging stage I, in the state 10_{L} of the crucible 10 in which it is in its large capacity configuration in which the first member 11 and the second member 21 are connected together, the crucible 10 is charged with a powder raw material Pp consisting of a mixture of calcium fluoride raw material powder and a scavenger. As the calcium fluoride raw material powder, chemically synthesized high purity calcium fluoride having particle diameter around 0.1 μm to 5 mm is used. The amount of the powder raw material that is charged is a weight that is calculated from the density of a calcium fluoride single crystal, so that the volume of the pre-treated product that solidifies after having been melted does not become greater than the capacity of the crucible 10_{S} in the small capacity configuration. The scavenger has the action to replace elements contained as impurities in the raw material with fluorine, and also to eliminate these impurity elements that have been replaced, in the form of volatile compounds. A fluorinating agent such as lead fluoride (PbF₂) or carbon tetrafluoride (CF₄) or the like may be used as the scavenger. For example, when lead fluoride is added to the raw material powder of calcium fluoride and heat is applied by the pre-treatment furnace to the mixture and it is melted, the oxygen in calcium oxide (CaO) included as an impurity in the raw material powder can be eliminated as lead oxide (PbO), that is volatile.

In the pre-processing stage II, the powder raw material Pp is solidified by cooling after it has been melted by the pre-treatment furnace 20, and thereby a pre-treated product Pb is manufactured that consists of a polycrystalline bulk of calcium fluoride. First, the crucible 10_{L} with the powder raw material Pp charged into it is supported upon the crucible support member 22, and then the bell jar 25 is closed and is evacuated by the vacuum apparatus, and the interior of the pre-treatment furnace 20 is brought down to a vacuum level of 10⁻³ Pa or less (and desirably down to a vacuum level of 10⁻⁴ Pa or less) and is maintained there. Next, heat is applied by the heater 26 and the temperature within the pre-treatment furnace 20 is raised to the temperature range of 1370° C.˜1450° C., that is higher than the melting point of calcium fluoride. After the powder raw material Pp has been melted, the heater 26 is turned off, and the material cools and solidifies. Due to this, the impurity elements included within the powder raw material are eliminated in the form of volatile compounds, and thereby a pre-treated product Pb consisting of a high purity polycrystalline bulk of calcium fluoride is manufactured in the crucible.

In the second member separation stage III, still with the pre-treated product Pb solidified and in the state of being held within the crucible 10_{L} that has been taken out from the pre-treatment furnace 20, the crucible 10 is transferred from the large capacity configuration crucible 10_{L} to the small capacity configuration crucible 10_{S}. In other words, the first member 11 is separated from the second member 12 by disengaging the connection construction 15 between the first member 11 and the second member 12, so that the crucible 10 is now transferred to the small capacity configuration crucible 10_{S}.

Finally, in the crystal growing stage IV, the pre-treated product Pb is melted in the crystal growing furnace 30, and a single crystal of calcium fluoride is manufactured by the Bridgman method. First, the second member 12 is taken off and the crucible 10_{S}, whose height has been reduced, is supported upon the support member 32 of the crystal growing furnace 30, the bell jar 35 is closed and the interior of the crystal growing furnace 30 is evacuated by the vacuum apparatus, and then the interior of the crystal growing furnace 30 is brought down to a vacuum level of 10⁻³ Pa or less (and desirably down to a vacuum level of 10⁻⁴ Pa or less) and is maintained there. At this time, the position of the crucible 10_{S} in the vertical direction is set by the up/down drive mechanism so that the crucible 10_{S} is positioned in the high temperature side furnace chamber 30. Then, using the upper portion heater 36a and the lower portion heater 36b, the temperature within the high temperature side furnace chamber 30a is raised to and maintained at the temperature range of 1370° C.˜1450° C., that is higher than the melting point of calcium fluoride, while the temperature within the low temperature side furnace chamber 30b is raised to and kept at a temperature range that is somewhat lower than the melting point of calcium fluoride. Then, while controlling the electrical power supplied to the upper portion heater 36a and to the lower portion heater 36b, by pulling the crucible 10_{S} downward into the low temperature side furnace chamber 30b at a speed of around 0.1˜5 mm/h with the up/down drive mechanism 33, a calcium fluoride single crystal is gradually grown from the pre-treated product that has been melted in the high temperature side furnace chamber 30a, from the lower portion of the crucible 10_{S} upwards, and the growth of this single crystal continues until it reaches the uppermost portion of the crucible. A calcium fluoride single crystal Pc may be obtained in this manner.

### Embodiment

Next, as an example of implementation, the manufacture of a single crystal of calcium fluoride will be explained. A powder raw material Pp was prepared by mixing lead fluoride (PbF₂) for serving as a scavenger into high purity calcium fluoride raw material powder of purity 99.0% or greater. And this powder raw material Pp was charged into a crucible 10_{L} in the large capacity configuration, consisting of a first member 11 and a second member 12 connected together (FIG. 1A, the powder raw material charging stage I).

Next, after having installed the crucible 10_{L} with the powder raw material Pp charged into it into the pre-treatment furnace 20, the interior of the pre-treatment furnace 20 was evacuated with the vacuum apparatus, and was brought down to a vacuum level of 10⁻⁴ Pa or less. In this state, the temperature of the interior of the pre-treatment furnace was raised to 850° C. and was kept there for eight hours, so that a reaction took place between the scavenger and the impurities in the calcium fluoride raw material powder. Next, the temperature of the interior of the pre-treatment furnace 20 was raised to 1400° C. and was kept in that state, and, after the powder raw material Pp had melted, the temperature of the interior of the pre-treatment furnace 20 was gradually lowered to room temperature, so that the molten material solidified, and thereby a pre-treated product Pb was obtained, consisting of a polycrystalline mass of calcium fluoride (FIG. 1B, the pre-processing stage II).

Next, after having taken the crucible 10_{L} out from the pre-treatment furnace 20, the second member 12 was separated from the first member 11 by breaking the connected state between the first member 11 and the second member 12, the second member 12 that was the crucible upper portion was taken off, and thereby the crucible was transferred to the small capacity configuration crucible 10_{S} with the pre-treated product Pb held within it (FIG. 1C, the second member separation stage III).

Next, the crucible 10_{S} with the pre-treated product Pb held within it was placed into the high temperature side furnace chamber 30a within the crystal growing furnace 30, that was then evacuated with the vacuum apparatus, so that the interior of the crystal growing furnace 30 was brought down to a vacuum level of 10⁻⁴ Pa or less. In this state, the temperature of the high temperature side furnace chamber 30a was gradually raised to 1410° C. by the upper portion heater 36a and the lower portion heater 36b, so that the pre-treated product Pb in the crucible was perfectly melted. Next, while controlling the electrical power supplied to the upper portion heater 36a and to the lower portion heater 36b, by pulling the crucible 10_{S} downward into the low temperature side furnace chamber 30b at a speed of around 0.5 mm/h, a calcium fluoride single crystal was gradually grown from the lower portion of the crucible 10_{S}, and thereby a calcium fluoride single crystal ingot Pc was obtained (FIG. 1D, the crystal growing stage IV).

Since large residual stresses were present in the calcium fluoride single crystal ingot after it had been extracted from the crucible 10_{S}, accordingly these residual stresses were reduced by implementing annealing at a level that did not fracture the ingot, and thereafter the crucible 10_{S} was taken out of the crystal growing furnace 30, so that a calcium fluoride single crystal ingot Pc was obtained (a heat processing stage, not shown in the drawings).

A test piece was cut out from the calcium fluoride single crystal ingot obtained in this manner and was irradiated with deep ultraviolet laser light of wavelength 193 nm, and the variations of transmittance and so on were measured. As a result, it was confirmed that the test piece had satisfactory durability with respect to deep ultraviolet laser light.

As has been explained above, according to the crucible for producing a compound crystal, the apparatus for producing a compound crystal, and the method for producing a compound crystal of the present invention, there is no need to perform any task of transferring the pre-treated product between the pre-processing stage in which the powder raw material for the compound is solidified after having been melted, and the crystal growing stage in which the single crystal of the compound is grown. Moreover, since in the crystal growing stage it is possible to remove the second member from the crucible and to put the crucible in its small capacity configuration into the crystal growing furnace, accordingly it is possible to manufacture the compound single crystal using a crystal growing furnace that is comparatively compact. Therefore, according to the present invention, it is possible to omit the troublesome task of transferring the pre-treated product that is troublesome to handle in a single mass from one crucible to another, and therefore, along with it being possible to reduce the producing cost, also mixing in of metallic impurities or the like accompanying such a transferring task can be suppressed, so that it is possible to obtain a compound single crystal of superior product quality. Moreover, since it is possible to use a crystal growing furnace that is comparatively compact, accordingly not only is the capital cost of the facility kept low, but also it is possible to reduce the producing cost of the compound single crystal product.

It should be understood that while, in the embodiment explained above, an example was shown in which the crucible 10 consisting of the first member 11 and the second member 12 was cylindrical, it would also be acceptable for the cross sectional shape of the crucible to be a quadrilateral or a polygon, such as in the case of a tube with corners, or to be elliptical, such as in the case of an elliptical tube. Moreover while, in the above embodiment of the present invention, an example was shown of producing a calcium fluoride single crystal, this being a representative example of a fluoride single crystal to be used for an optical element for the ultraviolet region, the present invention is not to be considered as being limited to the case of a calcium fluoride single crystal; for example, it is possible to obtain similar beneficial effects by applying the present invention to barium fluoride (BaF₂) or strontium fluoride (SrF₂), whose crystalline structures belong to the same cubic system as calcium fluoride and whose properties resemble those of calcium fluoride.

Moreover while, for the vacuum vessels, structures consisting of base plates and bell jars were shown as examples in the embodiment explained above, the shapes of the vacuum vessels and the materials used for them are not to be considered as being particularly limited in other implementations of the present invention; any structures can be employed without a problem, provided that they are capable of providing the desired temperature and the desired level of vacuum.

Furthermore, the subject of the crucible for producing a compound crystal, the subject of the apparatus for producing a compound crystal, and the subject of the method for producing a compound crystal of the present invention are not to be considered as being limited to a fluoride crystal; the subjects of the present invention also can include oxide crystals such as sapphire (α-Al₂O₃) or the like. Moreover, it should be understood that, when producing sapphire, it is desirable for the material for the crucible to be tungsten, molybdenum, or a tungsten-molybdenum alloy, and it is desirable not to evacuate the interiors of the pre-treatment furnace and the crystal growing furnace to vacuum, but rather to establish therein an atmosphere of an inert gas such as argon or the like.

While various embodiments of the present invention have been described above, the present invention is not to be considered as being limited by the details thereof.

What is claimed is:

1. A crucible for use in producing a compound crystal, the crucible comprising:
a first member having a bottom portion and a cylindrical portion integrated with the bottom portion; and
a second member that is hollow cylindrical and can be put into either a state of being connected to the cylindrical portion or into a state of being separated therefrom, wherein:
in a state in which the first member and the second member are connected together, a large capacity crucible for manufacture of a pre-treated product for the compound crystal is formed;
in a state in which the first member and the second member are separated from one another, a small capacity crucible for crystal growth of the compound crystal is formed; and
in the crucible, the pre-treated product is made by melting a powdery or granular compound raw material and then cooling and solidifying melted compound raw material in a pre-treatment furnace, and the compound crystal is grown by melting the pre-treated product and then cooling and solidifying melted pre-treated product in a crystal growing furnace.

2. The crucible for use in producing a compound crystal according to claim 1, wherein the compound is fluoride.

3. An apparatus for producing a compound crystal, comprising:
a vacuum vessel;
a crucible support member that supports a crucible in the interior of the vacuum vessel; and
a heater provided in the interior of the vacuum vessel, wherein
the crucible comprises a first member comprising a bottom portion and a cylindrical portion integrated with the bottom portion, and a second member that is hollow cylindrical and can be put either into a state of being connected to the cylindrical portion of the first member or into a state of being separated therefrom and
the crucible support member is configured to support the crucible in a state in which the second member of the crucible is connected to the first member.

4. The apparatus for producing a compound crystal according to claim 3, wherein the compound crystal is a fluoride crystal.

5. A method for producing a compound crystal using a crucible, the method comprising the steps of:
preparing step for preparing the crucible that comprises a first member having a bottom portion and a cylindrical portion integrated with the bottom portion, and a second member that is hollow cylindrical and can be put either into a state of being connected to the cylindrical portion or into a state of being separated therefrom;
a pre-processing step for making a pre-treated product for the compound crystal in the interior of the first member by, charging a raw material into the crucible in a state in which the second member is connected to the first member, melting the raw material, and then solidifying melted raw material;
a crucible separation step for separating the second member from the first member in a state in which the pre-treated product for the compound crystal has been made in the interior of the first member; and
a crystal growing step for melting the pre-treated compound product that has been made in the interior of the first member, and then solidifying melted pre-treated compound product and growing a crystal of the compound.

6. The method for producing a compound crystal using a crucible according to claim 5, wherein the compound is fluoride.
